(19) United States
(12) Patent Application Publication
(10) Pub. No.: US 2014/0266390 A1
(43) Pub. Date: Sep. 18, 2014

(54) TRANSCONDUCTANCE CIRCUIT AND FREQUENCY MIXER

(71) Applicant: HUAWEI TECHNOLOGIES CO., LTD., Shenzhen (CN)

(72) Inventor: Hongyu WANG, Shanghai (CN)

(73) Assignee: HUAWEI TECHNOLOGIES CO., LTD., Shenzhen (CN)

(21) Appl. No.: 14/192,517

(22) Filed: Feb. 27, 2014

(30) Foreign Application Priority Data
Mar. 13, 2013 (CN) 201310079274.X

(51) Int. Cl. H03D 7/14

(52) U.S. Cl. CPC H03D 7/1491
USPC 327/355

(57) ABSTRACT

The present invention provides a transconductance circuit and a frequency mixer. The transconductance circuit includes: a first transistor, a second transistor, a first impedor, a second impedor, a first input network, and a second input network, where a gate of the first transistor is connected to a source of the second transistor through the first input network and the first impedor; and a gate of the second transistor is connected to a source of the first transistor through the second input network and the second impedor. The present invention can enable a current that passes through a transconductance circuit to be reused between a first transistor and a second transistor, thereby improving the gain efficiency of the transconductance circuit and improving performance of the transconductance circuit.

### CROSS-REFERENCE TO RELATED APPLICATION

This application claims priority to Chinese Patent Application No. 201310079274.X, filed on Mar. 13, 2013, which is hereby incorporated by reference in its entirety.

### TECHNICAL FIELD

The present invention relates to the field of communications technologies, and in particular, to a transconductance circuit and a frequency mixer.

### BACKGROUND

In a base station and microwave communications system, an integrated chip is often used to replace a discrete commercial component on a board, which is significant to implementation of low-cost, highly-integrated, and intelligent communications products. An integrated chip, however, raises rigid requirements for performance of circuits, such as a frequency mixer.

A frequency mixer circuit can implement frequency conversion and is a very important circuit module at a radio frequency front end of a transceiver chip. The performance of an entire transceiver directly depends on the performance of the frequency mixer circuit, which affects an architecture selection and implementation of an entire solution. A gain, linearity, and noise of an active frequency mixer are key indicators of a frequency mixer. These indicators are mutually restricted in a design, which limits improvement of overall performance.

A transconductance circuit is the core circuit in a radio frequency chip and has a function of converting a voltage into a current in a frequency mixer. The transconductance circuit is located at an input terminal of the frequency mixer, and is a key part for implementing a high-performance active frequency mixer circuit. The transconductance circuit is a circuit that converts a voltage signal into a current signal. Equivalent transconductance of the transconductance circuit indicates a capability of the transconductance circuit in converting a voltage signal into a current signal, that is, indicates efficiency of the transconductance circuit. A degree of signal distortion caused during a conversion process is represented by linearity. Smaller distortion indicates higher linearity of the transconductance circuit, and causes a smaller impact on system performance.

Currently, a transconductance circuit that has found the widest application includes a common-source transconductance circuit and a common-gate transconductance circuit. A common-source transconductance circuit uses a negative feedback effect achieved by degeneration of inductance or resistance to improve the linearity of transconductance. The linearity of a common-source transconductance circuit is associated with the relationship between the small signal transconductance of an input transistor and degeneration inductance or resistance, whereas the linearity of a common-gate transconductance circuit is associated with the relationship between the small signal transconductance of an input transistor and the input impedance. The equivalent transconductance of a common-source transconductance circuit is mainly determined by the degeneration inductance, whereas the equivalent transconductance of a common-gate transconductance circuit is mainly determined by input impedance. In order to improve the linearity of the two types of transconductance circuits, the small signal transconductance of an input transistor needs to be increased, which is implemented by increasing power consumption; or, the degeneration inductance and input impedance need to be increased, which may reduce the gain efficiency, increase the noise, and increase difficulty in matching input impedance.

Therefore, during the design of a transconductance circuit, a gain, linearity, noise, and impedance matching are mutually restricted, which limits the improvement of performance of the transconductance circuit.

### SUMMARY

Embodiments of the present invention provide a transconductance circuit and a frequency mixer, which can improve performance of a transconductance circuit.

According to a first aspect, a transconductance circuit is provided, including: a first transistor, a second transistor, a first impedor, a second impedor, a first input network, and a second input network, where a gate of the first transistor is connected to a first input terminal of the transconductance circuit through the first input network, and a drain of the first transistor is connected to a first output terminal of the transconductance circuit; a gate of the second transistor is connected to a second input terminal of the transconductance circuit through the second input network, a drain of the second transistor is connected to a second output terminal of the transconductance circuit, and a source of the first transistor and a source of the second transistor are connected to each other and grounded through an inductor or a resistor; the gate of the first transistor is connected to the source of the second transistor through the first input network and the first impedor, and the first input network is serially connected to the first impedor; and the gate of the second transistor is connected to the source of the first transistor through the second input network and the second impedor, and the second input network is serially connected to the second impedor.

In a first possible implementation manner, the first input network includes a first capacitor and a third capacitor, the second input network includes a second capacitor and a fourth capacitor, the gate of the first transistor is connected to the first input terminal of the transconductance circuit through the first capacitor, and the drain of the first transistor is connected to the first output terminal of the transconductance circuit; the gate of the second transistor is connected to the second input terminal of the transconductance circuit through the second capacitor, and the drain of the second transistor is connected to the second output terminal of the transconductance circuit; the gate of the first transistor is connected to the source of the second transistor through the first impedor and the third capacitor; and the gate of the second transistor is connected to the source of the first transistor through the second impedor and the fourth capacitor.

With reference to the first possible implementation manner, in a second possible implementation manner, the gate of the first transistor is connected to the first input terminal of the transconductance circuit through the first capacitor, and the source of the first transistor is connected to the second input terminal of the transconductance circuit through the second impedor and the fourth capacitor; the gate of the second transistor is connected to the second input terminal of the transconductance circuit through the second capacitor; and the source of the second transistor is connected to the first input terminal of the transconductance circuit through the first impedor and the third capacitor.

With reference to the first possible implementation manner, in a third possible implementation manner, the gate of the first transistor is connected to the second input terminal of the transconductance circuit through the second impedor, the fourth capacitor, and the second capacitor; and the source of the second transistor is connected to the first input terminal of the transconductance circuit through the first impedor, the third capacitor, and the first capacitor.

With reference to the second possible implementation manner, in a fourth possible implementation manner, the gate of the first transistor is connected to the first input terminal of the transconductance circuit through the first capacitor and the third capacitor, and the source of the first transistor is connected to the second input terminal of the transconductance circuit through the second impedor and the second capacitor; and the gate of the second transistor is connected to the second input terminal of the transconductance circuit through the second capacitor and the fourth capacitor, and the source of the second transistor is connected to the first input terminal of the transconductance circuit through the first impedor and the first capacitor.

With reference to the first aspect or any one of the foregoing possible implementation manners, in a fifth possible implementation manner, a differential radio frequency signal is input from the first input terminal and the second input terminal; or, one of the first input terminal and the second input terminal is connected to a single-ended radio frequency signal, and the other of the first input terminal and the second input terminal is grounded.

With reference to the first aspect or any one of the foregoing possible implementation manners, in a sixth possible implementation manner, the source of the first transistor is grounded through a first inductor, and the source of the second transistor is grounded through a second inductor; or, the source of the first transistor and the source of the second transistor are grounded through a differential inductor.

With reference to the first aspect or any one of the foregoing possible implementation manners, in a seventh possible implementation manner, the first input network further includes a first resistor, and the second input network further includes a second resistor, where a bias voltage is applied on the gate of the first transistor through the first resistor, and a bias voltage is applied on the gate of the second transistor through the second resistor.

With reference to the first aspect or any one of the foregoing possible implementation manners, in an eighth possible implementation manner, the first transistor is a field-effect transistor or a junction transistor, and the second transistor is a field-effect transistor or a junction transistor.

According to a second aspect, a frequency mixer is provided, including: an input transconductance stage circuit, a switching stage circuit, and a load stage circuit, where the input transconductance stage circuit is connected to the load stage circuit through the switching stage circuit, and the input transconductance stage circuit is the transconductance circuit according to the first aspect or any one of the possible implementation manners of the first aspect.

With reference to the second aspect or any one of the foregoing possible implementation manners, in a ninth possible implementation manner, the frequency mixer according to the second aspect further includes a current extraction stage circuit, connected between a first output terminal and a second output terminal of the input transconductance stage circuit and the switching stage circuit, and configured to extract a current that passes through the switching stage circuit and the load stage circuit.

With reference to the second aspect or any one of the foregoing possible implementation manners, in a tenth possible implementation manner, the load stage circuit includes a differential output interface circuit that is formed by a third resistor and a fourth resistor; or, the load stage circuit includes an output interface circuit that is formed by a third inductor, a fourth inductor, and an N:1 balun, where N:1 is a coil turn ratio of the balun and N is a positive integer.

In the embodiments of the present invention, a gate of a first transistor of a transconductance circuit is connected to a source of a second transistor through a first input network and a first impedor; and a gate of the second transistor is connected to a source of the first transistor through a second input network and a second impedor, so that a current that passes through the transconductance circuit can be reused between the first transistor and the second transistor, thereby improving the gain efficiency of the transconductance circuit and improving performance of the transconductance circuit.

### BRIEF DESCRIPTION OF DRAWINGS

To describe the technical solutions in the embodiments of the present invention more clearly, the accompanying drawings required for describing the embodiments are briefly introduced in the following. Apparently, a person of ordinary skill in the art may still derive other drawings from these accompanying drawings without any creative efforts.

FIG. 1 is a schematic block diagram of a transconductance circuit according to an embodiment of the present invention;

FIG. 2 is a schematic block diagram of a transconductance circuit according to another embodiment of the present invention;

FIG. 3 is a schematic block diagram of a transconductance circuit according to still another embodiment of the present invention;

FIG. 4 is a schematic block diagram of a transconductance circuit according to another embodiment of the present invention;

FIG. 5 is a schematic block diagram of a transconductance circuit according to still another embodiment of the present invention;

FIG. 6 is a schematic block diagram of a frequency mixer according to an embodiment of the present invention;

FIG. 7 is a schematic block diagram of a frequency mixer according to another embodiment of the present invention; and

FIG. 8 is a schematic block diagram of a frequency mixer according to still another embodiment of the present invention.

### DESCRIPTION OF EMBODIMENTS

The following clearly describes the technical solutions in the embodiments of the present invention with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention without creative efforts shall fall within the protection scope of the present invention.

Currently, performance of a conventional transconductance circuit is low, and the gain and linearity of an active frequency mixer are low. To address this problem, embodiments of the present invention provide a high-performance transconductance circuit, which features high linearity and can achieve high gain efficiency. Meanwhile, with reference to the high-performance transconductance circuit in the embodiments of the present invention, a high-performance active frequency mixer is provided.

It should be noted that when it is described in the following that two components are connected, these two components may be directly connected, or connected indirectly through one or more intermediate components/media. Connection manners of two components include a contact manner and a non-contact manner, or include a wired manner and a wireless manner. A person skilled in the art may make equivalent substitutions or modifications on connection mode examples described in the following. All these substitutions or modifications shall fall within the scope of the present invention.

FIG. 1 is a schematic block diagram of a transconductance circuit 100 according to an embodiment of the present invention. The transconductance circuit 100 includes: a first transistor M1, a second transistor M2, a first impedor, a second impedor, a first input network 110, and a second input network 120.

A gate of the first transistor M1 is connected to a first input terminal of the transconductance circuit 100 through the first input network 110, and a drain of the first transistor M1 is connected to a first output terminal of the transconductance circuit 100; a gate of the second transistor M2 is connected to a second input terminal of the transconductance circuit 100 through the second input network 120, and a drain of the second transistor M2 is connected to a second output terminal of the transconductance circuit 100, a source of the first transistor and a source of the second transistor are connected to each other and grounded through an inductor or a resistor; the gate of the first transistor M1 is connected to the source of the second transistor M2 through the first input network 110 and the first impedor Z1, the first input network is serially connected to the first impedor; and the gate of the second transistor M2 is connected to the source of the first transistor M1 through the second input network 120 and the second impedor Z2, and the second input network is serially connected to the second impedor.

According to the embodiment of the present invention, the first transistor M1 and the second transistor M2 are an active transistor differential pair and are used to receive differential voltage signals, such as a positive voltage signal Vip and a negative voltage signal Vin, that are input from the first input terminal and the second input terminal of the transconductance circuit 100 respectively. The transconductance circuit 100 is configured to convert the input differential voltage signals into current signals Ion and Iop, and output these current signals respectively from the first output terminal and the second output terminal.

For example, the first input network 110 may include passive components, for example, a capacitor, which is not limited by the embodiment of the present invention. For example, the first input network 110 may also be a wire as long as it can simultaneously apply the input voltage signals on the gate of the first transistor M1 and the source of the second transistor M2. Similarly, the second input network 120 may also be a capacitor or a wire as long as it can simultaneously apply the input voltage signals on the gate of the second transistor M2 and the source of the first transistor M1.

For example, the source of the first transistor and the source of the second transistor may be connected to each other and grounded respectively through a first inductor (or a resistor) and a second inductor (or a resistor). Optionally, the source of the first transistor and the source of the second transistor may also be grounded through a center-tapped inductor or resistor, where the source of the first transistor is connected to one end of the inductor (or resistor), the source of the second transistor is connected to the other end of the inductor (or resistor), and the center tap of the inductor (or resistor) is grounded.

In the embodiment of the present invention, the gate of the first transistor of the transconductance circuit can be connected to the source of the second transistor through the first input network and the first impedor, and the gate of the second transistor can be connected to the source of the first transistor through the second input network and the second impedor. In this way, a current that passes through the transconductance circuit can be reused between the first transistor and the second transistor, which is equivalent to achieving the effects of common-source stage transconductance and common-gate stage transconductance, thereby improving the gain efficiency of the transconductance circuit and improving performance of the transconductance circuit.

According to the embodiment of the present invention, the first input network 110 includes a first capacitor and a third capacitor, the second input network 120 includes a second capacitor and a fourth capacitor, the gate of the first transistor M1 is connected to the first input terminal of the transconductance circuit 100 through the first capacitor, and the drain of the first transistor M1 is connected to the first output terminal of the transconductance circuit 100; the gate of the second transistor M2 is connected to the second input terminal of the transconductance circuit 100 through the second capacitor, and the drain of the second transistor M2 is connected to the second output terminal of the transconductance circuit 100; the gate of the first transistor M1 is connected to the source of the second transistor M2 through the first impedor Z1 and the third capacitor; and the gate of the second transistor M2 is connected to the source of the first transistor M1 through the second impedor Z2 and the fourth capacitor.

According to the embodiment of the present invention, the source of the first transistor M1 is connected to the second input terminal of the transconductance circuit 100 through the second impedor Z2, the fourth capacitor, and the second capacitor; and the source of the second transistor M2 is connected to the first input terminal of the transconductance circuit 100 through the first impedor Z1, the third capacitor, and the first capacitor.

In other words, the source of the first transistor M1 is serially connected to the gate of the second transistor M2 through the second impedor Z2, the fourth capacitor, and the second capacitor, and the source of the second transistor M2 is serially connected to the gate of the transistor M1 through the first impedor Z1, the third capacitor, and the first capacitor. Therefore, the transistor differential pair M1 and M2 can achieve the cross connection and reuse effects through the impedor.

Optionally, as another embodiment, the gate of the first transistor M1 is connected to the first input terminal of the transconductance circuit 100 through the first capacitor, and the source of the first transistor M1 is connected to the second input terminal of the transconductance circuit 100 through the second impedor Z2 and the fourth capacitor; the gate of the second transistor M2 is connected to the second input terminal of the transconductance circuit 100 through the second capacitor; and the source of the second transistor M2 is connected to the first input terminal of the transconductance circuit 100 through the first impedor Z1 and the third capacitor.

In other words, the source of the first transistor M1 is serially connected to the gate of the second transistor M2 through the second impedor Z2, the fourth capacitor, and the second capacitor, and the source of the second transistor M2 is serially connected to the gate of the transistor M1 through the first impedor Z1, the third capacitor, and the first capacitor. Therefore, the transistor differential pair M1 and M2 can achieve the cross connection and reuse effects through the impedor.

Optionally, as another embodiment, the gate of the first transistor M1 is connected to the first input terminal of the transconductance circuit 100 through the first capacitor and the third capacitor, and the source of the first transistor M1 is connected to the second input terminal of the transconductance circuit 100 through the second impedor Z2 and the second capacitor; and the gate of the second transistor M2 is connected to the second input terminal of the transconductance circuit 100 through the second capacitor and the fourth capacitor, and the source of the second transistor M2 is connected to the first input terminal of the transconductance circuit 100 through the first impedor Z1 and the first capacitor.

In other words, the source of the first transistor M1 is serially connected to the gate of the second transistor M2 through the second impedor Z2 and the fourth capacitor, and the source of the second transistor M2 is serially connected to the gate of the transistor M1 through the first impedor Z1 and the third capacitor. Therefore, the transistor differential pair M1 and M2 can achieve the cross connection and reuse effects through the impedor.

According to an embodiment of the present invention, a differential radio frequency signal is input from the first input terminal and the second input terminal.

For example, the differential radio frequency signal includes a positive voltage signal and a negative voltage signal.

Optionally, as another embodiment, one of the first input terminal and the second input terminal is connected to a single-ended radio frequency signal, and the other of the first input terminal and the second input terminal is grounded.

For example, the single-ended radio frequency signal may be the positive voltage signal or the negative voltage signal. In the embodiment of the present invention, the transistor differential pair M1 and M2 can achieve the cross connection and reuse effects through the impedor. Therefore, it is possible to use a single-ended radio frequency signal.

According to an embodiment of the present invention, the source of the first transistor M1 is grounded through the first inductor, and the source of the second transistor M2 is grounded through the second inductor; or the source of the first transistor M1 and the source of the second transistor M2 are grounded through a differential inductor.

For example, the differential inductor is a center-tapped inductor. One end of the differential inductor is connected to the source of the first transistor M1, the other end is connected to the source of the second transistor M2, and the center tap of the differential inductor is grounded. The first inductor, the second inductor, and the differential inductor can be degeneration inductors. In a transconductance circuit, the negative feedback effect of a degeneration inductor is used to improve the linearity of the transconductance circuit.

Optionally, as another embodiment, the first input network 110 further includes a first resistor, and the second input network 120 further includes a second resistor, where a bias voltage is applied on the gate of the first transistor M1 through the first resistor, and a bias voltage is applied on the gate of the second transistor M2 through the second resistor.

For example, a bias voltage Vbias may come from a current mirror and is used to provide a bias for the transconductance circuit.

According to the embodiment of the present invention, the first transistor M1 is a field-effect transistor or a junction transistor, and the second transistor M2 is a field-effect transistor or a junction transistor.

For example, a field-effect transistor may be a Metal-Oxide-Semiconductor Field-Effect Transistor (Metal-Oxide-Semiconductor Field-Effect Transistor, MOSFET), and a junction transistor can be a bipolar junction transistor.

FIG. 2 is a schematic block diagram of a transconductance circuit 200 according to another embodiment of the present invention. FIG. 2 is an example of the transconductance circuit 100 shown in FIG. 1.

The transconductance circuit 200 may include a transistor differential pair, a first input network 210, a second input network 220, a first impedor Z1, and a second impedor Z2, where the transistor differential pair is formed by active components, including a first transistor M1 and a second transistor M2, and the first input network 210 and the second input network 220 are formed by passive components. For example, the first input network 210 may include a first capacitor C1, a third capacitor C3, and a first resistor R1. The second input network 220 may include a second capacitor C2, a fourth capacitor C4, and a second resistor R2.

A gate of the first transistor M1 is connected to a first input terminal of the transconductance circuit 200 through the first capacitor C1, the gate of the first transistor M1 is connected to a source of the second transistor M2 through the third capacitor C3 and the first impedor Z1, a source of the first transistor M1 is connected to a second input terminal of the transconductance circuit 200 through the second impedor Z2, the fourth capacitor C4, and the second capacitor C2, that is, a positive voltage signal Vip of input differential signals is applied on the gate of the first transistor M1 through the first capacitor C1, whereas a negative voltage signal Vin of the input differential signals is applied on the source of the first transistor M1 through the second capacitor C2, the fourth capacitor C4, and the second impedor Z2.

A gate of the second transistor M2 is connected to the second input terminal of the transconductance circuit 200 through the second capacitor C2, the gate of the second transistor M2 is connected to the source of the first transistor M1 through the fourth capacitor C4 and the second impedor Z2, the source of the second transistor M2 is connected to the first input terminal of the transconductance circuit through the first impedor Z1, the third capacitor C3, and the first capacitor C1, that is, the negative voltage signal Vin of the input differential signals is applied on the gate of the second transistor M2 through the second capacitor C2, and the positive voltage signal Vip of the input differential signals is applied on the source of the second transistor M2 through the first capacitor C1, the third capacitor C3, and the first impedor Z1.

A drain of the first transistor M1 is connected to a first output terminal of the transconductance circuit 200 to output a current signal Ion, and a drain of the second transistor M2 is connected to a second output terminal of the transconductance circuit 200 to output a current signal Iop.

In addition, the source of the first transistor M1 and the source of the second transistor M2 can be connected to each other through degeneration inductors L1 and L2, and grounded through the degeneration inductors L1 and L2.

The impedance values of the first impedor Z1 and the second impedor Z2 are the same, and an inductor or a resistor can be selected according to actual applications. For example, an inductor can be used in a low noise scenario, whereas a resistor can be used in a bandwidth input matching scenario and a scenario that has rigid requirements for a component area.

The capacitance value of the first capacitor C1 is equal to the capacitance value of the second capacitor C2, and the capacitance value of the third capacitor C3 is equal to the capacitance value of the fourth capacitor C4. These capacitors can be blocking capacitors that are used to block DC signals and let AC signals pass.

The active components, including the first transistor M1 and the second transistor M2, and the passive components, including the first impedor Z1, the second impedor Z2, the degeneration inductor L1, and the degeneration inductor L2, jointly take part in the matching of an input network, where the first impedor Z1 and the second impedor Z2 play a dominant role during matching. In the embodiment of the present invention, the first impedor Z1 and the second impedor Z2 can be chosen as a resistor or an inductor according to demands to implement broad matching performance. Compared with a common-source transconductance circuit, the transconductance circuit in the embodiment of the present invention has the advantage that no extra inductor needs to be serially connected during input matching.

The gates of the first transistor M1 and the second transistor M2 are connected to a bias voltage Vbias respectively through the first resistor R1 and the second resistor R2. The bias voltage Vbias comes from a current mirror, which provides a bias voltage for the transconductance circuit.

Owing to the skillful connections on the circuit, the transconductance circuit in the embodiment of the present invention achieves that a current that passes through the transconductance circuit is reused between a first transistor M1 and a second transistor M2, and the gain efficiency is the sum of the gain efficiency of a conventional common-source transconductance circuit and the gain efficiency of a conventional common-gate transconductance circuit.

The following formulas are used to derive the gain efficiency of the transconductance circuit in the embodiment of the present invention. To reveal the nature of the transconductance circuit in the embodiment of the present invention and derive the small signal equivalent transconductance of the transconductance circuit, impacts of a parasitic capacitor of a transistor can be ignored. The equivalent transconductance can be expressed as follows:

$${G}_{m} = \frac{\frac{1}{{Z}_{3}} + \frac{1}{{L}_{1} S}}{\frac{1}{{G}_{m}} ( \frac{1}{{Z}_{3}} + \frac{1}{{L}_{1} S / 2} ) + 1} \qquad ( 1 )$$

where Gₘ is the equivalent transconductance of the transconductance circuit, gₘ is the small signal transconductance of the input transistor, L₁ is the degeneration inductance, Z₁ is the input impedance, and S=j*2πf is a parameter that indicates the frequency. In a common radio frequency and microwave application scenario and within a concerned frequency range, generally, gₘ·Z>>1. Here, Z=Z₃ or Z=L₁S. Therefore, formula (1) can be simplified as follows:

$${G}_{m} \approx \frac{1}{{Z}_{3}} + \frac{1}{{L}_{1} S} \qquad ( 2 )$$

It can be inferred from formula (2) that the gain efficiency of the transconductance circuit provided by the present invention is the sum of the gain efficiency of a common-source transconductance circuit and the gain efficiency of a common-gate transconductance circuit.

FIG. 3 is a schematic block diagram of a transconductance circuit 300 according to still another embodiment of the present invention. FIG. 3 is an example of the transconductance circuit 100 shown in FIG. 1. Except that the first input network 310 and the second input network 320 in the transconductance circuit 300 shown in FIG. 3 are different from the first input network 210 and the second input network 220 in the transconductance circuit 200 shown in FIG. 2, the remaining parts of the transconductance circuit 300 in FIG. 3 are similar to those of the transconductance circuit in FIG. 2. Therefore, detailed descriptions are omitted as appropriate herein.

The transconductance circuit 300 may include a transistor differential pair, a first input network 310, a second input network 320, a first impedor Z1, and a second impedor Z2, where the transistor differential pair is formed by active components, including a first transistor M1 and a second transistor M2, and the first input network 310 and the second input network 320 are formed by passive components. For example, the first input network 310 may include a first capacitor C1, a third capacitor C3, and a first resistor R1. The second input network 320 may include a second capacitor C2, a fourth capacitor C4, and a second resistor R2.

A gate of the first transistor M1 is connected to a first input terminal of the transconductance circuit 300 through the first capacitor C1, the gate of the first transistor M1 is connected to a source of the second transistor M2 through the first capacitor C1, the third capacitor C3, and the first impedor Z1, a source of the first transistor M1 is connected to a second input terminal of the transconductance circuit 300 through the second impedor Z2 and the fourth capacitor C4, that is, a positive voltage signal Vip of input differential signals is applied on the gate of the first transistor M1 through the first capacitor C1, and a negative voltage signal Vin of the input differential signals is applied on the source of the first transistor M1 through the fourth capacitor C4 and the second impedor Z2.

A gate of the second transistor M2 is connected to the second input terminal of the transconductance circuit 300 through the second capacitor C2, the gate of the second transistor M2 is connected to the source of the first transistor M1 through the second capacitor C2, the fourth capacitor C4, and the second impedor Z2, the source of the second transistor M2 is connected to the first input terminal of the transconductance circuit 300 through the first impedor Z1 and the third capacitor C3, that is, the negative voltage signal Vin of the input differential signals is applied on the gate of the second transistor M2 through the second capacitor C2, and the positive voltage signal Vip of the input differential signals is applied on the source of the second transistor M2 through the third capacitor C3 and the first impedor Z1.

FIG. 4 is a schematic block diagram of a transconductance circuit 400 according to another embodiment of the present invention. FIG. 4 is an example of the transconductance circuit 100 shown in FIG. 1. Except that the first input network 410 and the second input network 420 in the transconductance circuit 400 shown in FIG. 4 are different from the first input network 210 and the second input network 220 in the transconductance circuit 200 shown in FIG. 2, the remaining parts of the transconductance circuit 400 in FIG. 4 are similar to those of the transconductance circuit in FIG. 2. Therefore, detailed descriptions are omitted as appropriate herein.

The transconductance circuit 400 may include a transistor differential pair, a first input network 410, a second input network 420, a first impedor Z1, and a first impedor Z2, where the transistor differential pair is formed by active components, including a first transistor M1 and a second transistor M2, and the first input network 410 and the second input network 420 are formed by passive components. For example, the first input network 410 may include a first capacitor C1, a third capacitor C3, and a first resistor R1. The first input network 420 may include a second capacitor C2, a fourth capacitor C4, and a second resistor R2.

A gate of the first transistor M1 is connected to a first input terminal of the transconductance circuit 400 through the third capacitor and the first capacitor C1, the gate of the first transistor M1 is connected to a source of the second transistor M2 through the third capacitor C3 and the first impedor Z1, a source of the first transistor M1 is connected to a second input terminal of the transconductance circuit 200 through the second impedor Z2 and the second capacitor C2, that is, a positive voltage signal Vip of input differential signals is applied on the gate of the first transistor M1 through the first capacitor C1 and the third capacitor C3, and a negative voltage signal Vin of the input differential signals is applied on the source of the first transistor M1 through the second capacitor C2 and the second impedor Z2.

A gate of the second transistor M2 is connected to the second input terminal of the transconductance circuit 200 through the fourth capacitor C4 and the second capacitor C2, the gate of the second transistor M2 is connected to the source of the first transistor M1 through the fourth capacitor C4 and the second impedor Z2, the source of the second transistor M2 is connected to the first input terminal of the transconductance circuit through the first impedor Z1 and the first capacitor C1, that is, the negative voltage signal Vin of the input differential signals is applied on the gate of the second transistor M2 through the second capacitor C2 and the fourth capacitor C4, and the positive voltage signal Vip of the input differential signals is applied on the source of the second transistor M2 through the first capacitor C1 and the first impedor Z1.

FIG. 5 is a schematic block diagram of a transconductance circuit 500 according to still another embodiment of the present invention. FIG. 5 is an example of the transconductance circuit 100 shown in FIG. 1. Unlike the transconductance circuit 200 in FIG. 2, sources of a first transistor M1 and a second transistor M2 in the transconductance circuit 500 in FIG. 5 are connected through a differential degeneration inductor L and grounded through a center tap of the differential inductor. Although the first input network 510 and the second input network 520 in FIG. 5 are respectively the same as the first input network 210 and the second input network 220, a person skilled in the art may understand that, the first input network 510 and the second input network 520 can be respectively replaced by the first input network 310 and the second input network 320, or by the first input network 410 and the second input network 420.

The highly efficient transconductance circuits in the embodiments of the present invention are described in the foregoing. The following describes in detail frequency mixers in the embodiments of the present invention with reference to FIG. 6 to FIG. 8.

FIG. 6 is a block diagram of a frequency mixer 600 according to an embodiment of the present invention. The frequency mixer 600 includes: an input transconductance stage circuit 610, a switching stage circuit 620, and a load stage circuit 630, where the input transconductance stage circuit 610 is connected to the load stage circuit 630 through the switching stage circuit 620.

The input transconductance stage circuit 610 includes: a first transistor M1, a second transistor M2, a first impedor Z1, a second impedor Z2, a first input network 611, and a second input network 612, where a gate of the first transistor M1 is connected to a first input terminal of the input transconductance stage circuit 610 through the first input network 611, and a drain of the first transistor M1 is connected to a first output terminal of the input transconductance stage circuit 610; a gate of the second transistor M2 is connected to a second input terminal of the input transconductance stage circuit 610 through the second input network 612, and a drain of the second transistor M2 is connected to a second output terminal of the input transconductance stage circuit 610; the gate of the first transistor M1 is connected to a source of the second transistor M2 through the first input network 611 and the first impedor Z1; and the gate of the second transistor M2 is connected to a source of the first transistor M1 through the second input network 612 and the second impedor Z2.

According to the embodiment of the present invention, the input transconductance stage circuit 610 is configured to convert an input voltage signal into a current signal, the switching stage circuit 620 is configured to implement frequency conversion by means of switching, and the load stage circuit 630 is configured to convert a current signal into a voltage signal for output.

According to the embodiment of the present invention, the first input network 611 includes a first capacitor and a third capacitor, the second input network 612 includes a second capacitor and a fourth capacitor, the gate of the first transistor M1 is connected to the first input terminal of the input transconductance stage circuit 610 through the first capacitor, and the drain of the first transistor M1 is connected to the first output terminal of the input transconductance stage circuit 610; the gate of the second transistor M2 is connected to the second input terminal of the input transconductance stage circuit 610 through the second capacitor, and the drain of the second transistor M2 is connected to the second output terminal of the input transconductance stage circuit 610, and the source of the first transistor M1 and the source of the second transistor M2 are connected to each other and grounded through an inductor or a resistor; the gate of the first transistor M1 is connected to the source of the second transistor M2 through the first impedor and the third capacitor; and the gate of the second transistor M2 is connected to the source of the first transistor M1 through the second impedor Z2 and the fourth capacitor.

Embodiments of the present invention can be combined with the foregoing high-performance input transconductance stage circuit. A current of the input transconductance stage circuit can be reused between a first transistor and a second transistor, thereby improving the gain efficiency of the input transconductance stage circuit and implementing a high-linearity, high-gain frequency mixer.

According to the embodiment of the present invention, the source of the first transistor M1 is connected to the second input terminal of the input transconductance stage circuit 610 through the second impedor, the fourth capacitor, and the second capacitor; and the source of the second transistor M2 is connected to the first input terminal of the input transconductance stage circuit 610 through the first impedor, the third capacitor, and the first capacitor.

Optionally, as another embodiment, the gate of the first transistor M1 is connected to the first input terminal of the input transconductance stage circuit 610 through the first capacitor, and the source of the first transistor M1 is connected to the second input terminal of the input transconductance stage circuit 610 through the second impedor and the fourth capacitor; the gate of the second transistor M2 is connected to the second input terminal of the input transconductance stage circuit 610 through the second capacitor; and the source of the second transistor M2 is connected to the first input terminal of the input transconductance stage circuit 610 through the first impedor and the third capacitor.

Optionally, as another embodiment, the gate of the first transistor M1 is connected to the first input terminal of the input transconductance stage circuit 610 through the first capacitor and the third capacitor, and the source of the first transistor M1 is connected to the second input terminal of the input transconductance stage circuit through the second impedor and the second capacitor; and the gate of the second transistor M2 is connected to the second input terminal of the input transconductance stage circuit 610 through the second capacitor and the fourth capacitor, and the source of the second transistor M2 is connected to the first input terminal of the input transconductance stage circuit 610 through the first impedor and the first capacitor.

According to an embodiment of the present invention, a differential radio frequency signal is input from the first input terminal and the second input terminal.

Optionally, as another embodiment, one of the first input terminal and the second input terminal is connected to a single-ended radio frequency signal, and the other of the first input terminal and the second input terminal is grounded.

According to the embodiment of the present invention, the source of the first transistor M1 is grounded through the first inductor, and the source of the second transistor M2 is grounded through the second inductor.

Optionally, as another embodiment, the source of the first transistor M1 and the source of the second transistor M2 are grounded through a differential inductor.

Optionally, as another embodiment, the first input network 611 further includes a first resistor, and the second input network 612 further includes a second resistor, where a bias voltage is applied on the gate of the first transistor M1 through the first resistor, and a bias voltage is applied on the gate of the second transistor M2 through the second resistor.

According to the embodiment of the present invention, the first transistor M1 is a field-effect transistor or a junction transistor, and the second transistor M2 is a field-effect transistor or a junction transistor.

Optionally, as another embodiment, the frequency mixer further includes: a current extraction stage circuit 640, connected between the first output terminal and the second output terminal of the input transconductance stage circuit 610 and the switching stage circuit 620, and is configured to extract a current that passes through the switching stage circuit 620 and the load stage circuit 630.

According to the embodiment of the present invention, the load stage circuit 630 includes: a differential output interface circuit that is formed by a third resistor and a fourth resistor.

Optionally, as another embodiment, the load stage circuit 630 includes an output interface circuit that is formed by a third inductor, a fourth inductor, and an N:1 balun, where N:1 is a coil turn ratio of the balun and N is a positive integer.

FIG. 7 is a schematic block diagram of a frequency mixer 700 according to another embodiment of the present invention. The frequency mixer 700 in FIG. 7 is an example of the frequency mixer 600 in FIG. 6.

The frequency mixer 700 is an active frequency mixer, which includes: an input transconductance stage circuit 710, a current extraction stage circuit 740, a Gilbert switching stage circuit 720, and an off-chip balun component 730.

The input transconductance stage circuit 710 can be the transconductance circuit 200 in FIG. 2, and details are not described herein again.

The current extraction stage circuit 740 is formed by a third resistor R3, a fourth resistor R4, and a pull-up current source Ictl. Specifically, the third resistor R3 and the fourth resistor R4 are serially connected respectively and connected across a drain of a first transistor M1 and a drain of a second transistor M2 in crossed manner. The pull-up current source is connected to the connection point between R3 and R4. The third resistor R3, the fourth resistor R4, and the pull-up current source Ictl together form a current extraction stage circuit. By means of extracting the current that passes through the switching stage circuit 620 and the load stage circuit 630, the noise of the switching stage circuit can be reduced.

The switching stage circuit 620 is formed by a third transistor M3, a fourth transistor M4, a fifth transistor M5, and a sixth transistor M6. That is, two pairs of transistor switches are connected in crossed manner to form a Gilbert switching circuit, where a source of the third transistor M3 is connected to a source of the fourth transistor M4 and to the drain of the first transistor M1, and a source of the fifth transistor M5 is connected to a source of the sixth transistor M6 and to the drain of the second transistor M2. A drain of the third transistor M3 is connected to a drain of the fifth transistor M5, and a drain of the fourth transistor M4 is connected to a drain of the sixth transistor M6. A gate of the fourth transistor M4 is connected to a gate of the fifth transistor, and a gate of the third transistor M3 and a gate of the sixth transistor receive input differential signals Lop and Lop.

The load stage circuit 630 is formed by a third inductor L3, a fourth inductor L4, and an off-chip component. The off-chip component may be an N:1 differential to single-ended balun. The off-chip component is adopted mainly to reserve sufficient voltage headroom for a drain of the switching stage circuit, thereby improving the linearity. This configuration of the load stage circuit is more suitable for a low-voltage application scenario to save the power consumption of the circuit. In addition, an N:1 balun is used to connect an external 50 ohm matching component to output higher power and provide an extra power gain.

It should be understood that the embodiment in FIG. 7 is described by using an example in which the input transconductance stage circuit 710 is the transconductance circuit 200 in FIG. 2. A person skilled in the art may understand that the input transconductance stage circuit 710 can be replaced by any transconductance circuit in FIG. 3 to FIG. 5.

FIG. 8 is a block diagram of a frequency mixer 800 according to still another embodiment of the present invention. The frequency mixer 800 is a high-voltage gain, fully integrated, and passive frequency mixer circuit. Compared with the frequency mixer 700 in FIG. 7, the frequency mixer 800 does not adopt an off-chip passive component and is a fully integrated technical solution.

The difference between the embodiment in FIG. 8 and the active frequency mixer in FIG. 7 lies in load impedance. On a load stage circuit of the frequency mixer 800, a fifth resistor R5 and a sixth resistor R6 inside the chip form a differential output interface to obtain a high voltage gain. This configuration of the frequency mixer 800 is suitable for an application scenario where the differential voltage drive is used as the interface.

It should be understood that the embodiment in FIG. 8 is described by using an example in which the input transconductance stage circuit 810 is the input transconductance stage circuit 200 in FIG. 2. A person skilled in the art should understand that the input transconductance stage circuit 810 can be replaced by any transconductance circuit in FIG. 3 to FIG. 5.

The highly efficient transconductance circuit and active frequency mixer implemented by the present invention can be widely applied on a high performance chip of a base station or microwave product. In addition, due to its characteristic of high efficiency, the transconductance circuit can be applied on a terminal chip to achieve low power consumption and a low cost.

A person of ordinary skill in the art should be aware that each unit described in embodiments disclosed in this document can be implemented by electronic hardware, firmware, computer software, or a combination of any two of the foregoing items.

Although the present invention is described in detail with reference to the accompanying drawings and exemplary embodiments, the descriptions are not intended to limit the present invention. Without departing from the nature of the present invention, a person of ordinary skill in the art can make equivalent modifications or substitutions to the embodiments of the present invention. All these modifications or substitutions shall fall within the scope of the present invention.

1. A transconductance circuit, comprising: a first transistor, a second transistor, a first impedor, a second impedor, a first input network, and a second input network, wherein:
a gate of the first transistor is connected to a first input terminal of the transconductance circuit through the first input network, and a drain of the first transistor is connected to a first output terminal of the transconductance circuit;
a gate of the second transistor is connected to a second input terminal of the transconductance circuit through the second input network, a drain of the second transistor is connected to a second output terminal of the transconductance circuit, and a source of the first transistor and a source of the second transistor are connected to each other and grounded through an inductor or a resistor;
the gate of the first transistor is connected to the source of the second transistor through the first input network and the first impedor, and the first input network is serially connected to the first impedor; and
the gate of the second transistor is connected to the source of the first transistor through the second input network and the second impedor, and the second input network is serially connected to the second impedor.

2. The transconductance circuit according to claim 1, wherein the first input network comprises a first capacitor and a third capacitor, the second input network comprises a second capacitor and a fourth capacitor, the gate of the first transistor is connected to the first input terminal of the transconductance circuit through the first capacitor, and the drain of the first transistor is connected to the first output terminal of the transconductance circuit;
the gate of the second transistor is connected to the second input terminal of the transconductance circuit through the second capacitor, and the drain of the second transistor is connected to the second output terminal of the transconductance circuit;
the gate of the first transistor is connected to the source of the second transistor through the first impedor and the third capacitor; and
the gate of the second transistor is connected to the source of the first transistor through the second impedor and the fourth capacitor.

3. The transconductance circuit according to claim 2, wherein the source of the first transistor is connected to the second input terminal of the transconductance circuit through the second impedor, the fourth capacitor, and the second capacitor; and
the source of the second transistor is connected to the first input terminal of the transconductance circuit through the first impedor, the third capacitor, and the first capacitor.

4. The transconductance circuit according to claim 2, wherein the gate of the first transistor is connected to the first input terminal of the transconductance circuit through the first capacitor, and the source of the first transistor is connected to the second input terminal of the transconductance circuit through the second impedor and the fourth capacitor; and
the gate of the second transistor is connected to the second input terminal of the transconductance circuit through the second capacitor, and the source of the second transistor is connected to the first input terminal of the transconductance circuit through the first impedor and the third capacitor.

5. The transconductance circuit according to claim 2, wherein the gate of the first transistor is connected to the first input terminal of the transconductance circuit through the first capacitor and the third capacitor, and the source of the first transistor is connected to the second input terminal of the transconductance circuit through the second impedor and the second capacitor; and
the gate of the second transistor is connected to the second input terminal of the transconductance circuit through the second capacitor and the fourth capacitor, and the source of the second transistor is connected to the first input terminal of the transconductance circuit through the first impedor and the first capacitor.

6. The transconductance circuit according to claim 2, wherein:
a differential radio frequency signal is input from the first input terminal and the second input terminal.

7. The transconductance circuit according to claim 2, wherein,
the source of the first transistor is grounded through a first inductor, and the source of the second transistor is grounded through a second inductor.

8. The transconductance circuit according to claim 2, wherein the first input network further comprises a first resistor, and the second input network further comprises a second resistor, wherein a bias voltage is applied on the gate of the first transistor through the first resistor, and a bias voltage is applied on the gate of the second transistor through the second resistor.

9. The transconductance circuit according to claim 2, wherein the first transistor is a field-effect transistor or a junction transistor, and the second transistor is a field-effect transistor or a junction transistor.

10. A frequency mixer, comprising: an input transconductance stage circuit, a switching stage circuit, and a load stage circuit, wherein the input transconductance stage circuit is connected to the load stage circuit through the switching stage circuit, and the input transconductance stage circuit comprising: a first transistor, a second transistor, a first impedor, a second impedor, a first input network, and a second input network, wherein:
a gate of the first transistor is connected to a first input terminal of the input transconductance circuit through the first input network, and a drain of the first transistor is connected to a first output terminal of the transconductance circuit;
a gate of the second transistor is connected to a second input terminal of the transconductance circuit through the second input network, a drain of the second transistor is connected to a second output terminal of the transconductance circuit, and a source of the first transistor and a source of the second transistor are connected to each other and grounded through an inductor or a resistor;
the gate of the first transistor is connected to the source of the second transistor through the first input network and the first impedor, and the first input network is serially connected to the first impedor; and
the gate of the second transistor is connected to the source of the first transistor through the second input network and the second impedor, and the second input network is serially connected to the second impedor.

11. The frequency mixer according to claim 10, wherein the first input network comprises a first capacitor and a third capacitor, the second input network comprises a second capacitor and a fourth capacitor, the gate of the first transistor is connected to the first input terminal of the transconductance circuit through the first capacitor, and the drain of the first transistor is connected to the first output terminal of the transconductance circuit;
the gate of the second transistor is connected to the second input terminal of the transconductance circuit through the second capacitor, and the drain of the second transistor is connected to the second output terminal of the transconductance circuit;
the gate of the first transistor is connected to the source of the second transistor through the first impedor and the third capacitor; and
the gate of the second transistor is connected to the source of the first transistor through the second impedor and the fourth capacitor.

12. The frequency mixer according to claim 11, wherein the source of the first transistor is connected to the second input terminal of the transconductance circuit through the second impedor, the fourth capacitor, and the second capacitor; and
the source of the second transistor is connected to the first input terminal of the transconductance circuit through the first impedor, the third capacitor, and the first capacitor.

13. The frequency mixer according to claim 11, wherein the gate of the first transistor is connected to the first input terminal of the transconductance circuit through the first capacitor, and the source of the first transistor is connected to the second input terminal of the transconductance circuit through the second impedor and the fourth capacitor; and
the gate of the second transistor is connected to the second input terminal of the transconductance circuit through the second capacitor, and the source of the second transistor is connected to the first input terminal of the transconductance circuit through the first impedor and the third capacitor.

14. The frequency mixer according to claim 11, wherein the gate of the first transistor is connected to the first input terminal of the transconductance circuit through the first capacitor and the third capacitor, and the source of the first transistor is connected to the second input terminal of the transconductance circuit through the second impedor and the second capacitor; and
the gate of the second transistor is connected to the second input terminal of the transconductance circuit through the second capacitor and the fourth capacitor, and the source of the second transistor is connected to the first input terminal of the transconductance circuit through the first impedor and the first capacitor.

15. (canceled)

16. (canceled)

17. The frequency mixer according to claim 11, wherein the first input network further comprises a first resistor, and the second input network further comprises a second resistor, wherein a bias voltage is applied on the gate of the first transistor through the first resistor, and a bias voltage is applied on the gate of the second transistor through the second resistor.

18. (canceled)

19. The frequency mixer according to claim 10, further comprising a current extraction stage circuit, connected between a first output terminal and a second output terminal of the input transconductance stage circuit and the switching stage circuit, and configured to extract a current that passes through the switching stage circuit and the load stage circuit.

20. The frequency mixer according to claim 10, wherein,
the load stage circuit comprises a differential output interface circuit that is formed by a third resistor and a fourth resistor.

21. The transconductance circuit according to claim 2, wherein: one of the first input terminal and the second input terminal is connected to a single-ended radio frequency signal, and the other of the first input terminal and the second input terminal is grounded.

22. The transconductance circuit according to claim 2, wherein,
the source of the first transistor and the source of the second transistor are grounded through a differential inductor.

23. The frequency mixer according to claim 10, wherein,
the load stage circuit comprises an output interface circuit that is formed by a third inductor, a fourth inductor, and an N:1 balun, wherein N:1 is a coil turn ratio of the balun and N is a positive integer.
